(19) United States
(12) Patent Application Publication
(10) Pub. No.: US 2021/0278661 A1
(43) Pub. Date: Sep. 9, 2021

(54) APPARATUS FOR DEFLECTING AN OPTICAL DEVICE

(71) Applicant: Optotune AG, Dietikon (CH)

(72) Inventors: Michael Zihlmann, Dietikon (CH); Wolfgang Zesch, Dietikon (CH); Ulrich Leidenberger, Dietikon (CH); Xavier Palou, Dietikon (CH)

(73) Assignee: Optotune AG, Dietikon (CH)

(21) Appl. No.: 17/191,740

(22) Filed: Mar. 4, 2021

(30) Foreign Application Priority Data
Mar. 5, 2020 (DE) 102020105983.3

(51) Int. Cl. G02B 26/10

(52) U.S. Cl. CPC G02B 26/101

(57) ABSTRACT

An apparatus for deflecting with respect to one or more axes a device mounted on the apparatus, the apparatus comprising: a mounting support; a device chassis defining a plane and a clockwise direction in the plane, wherein the device chassis comprises two or more arm bridges, wherein a first arm bridge is extending from a first side of the device chassis and a second arm bridge is extending from a second and opposite side of the device chassis. One or more arm bridges comprising a first arm extending continuously in a clockwise direction to a first standoff and a second arm extending continuously in an anti-clockwise direction to a second standoff. The apparatus comprising one or more standoff supports comprised between each standoff and the mounting support.

### CROSS REFERENCE TO RELATED APPLICATIONS

Benefit is claimed to German Patent Application No. DE102020105983.3 filed Mar. 5, 2020, the contents of which are incorporated by referenced herein in their entirety.

### FIELD

The present invention relates to actuating devices for deflecting a device such as an optical device, for example via rotation around or translation along one or more axes.

### BACKGROUND

Optical apparatuses, for example comprising sensors or light transmitters, for example imaging sensors or light projectors, may comprise actuating devices to orient, translate, or oscillate a light's optical path. For example, the resolution of an image generated by an imaging device may be increased by computationally stitching a plurality of images acquired by the imaging sensor over a plurality of spatially distinct imaging configurations. There is, for example, a need for devices to reliably configure the plurality of spatially distinct imaging configurations. More specifically, there is a need to reliably and repeatably obtain the configurations within changing environmental conditions, for example one or more of changing temperature, vibrations, structural support geometry, material aging, and energy supply. There is also a need for actuators that have a low energy consumption, low acoustic signature, and reduced sensitivity to material aging.

### SUMMARY

The present invention relates to an apparatus for oscillating a device with respect to one or more axes, for example one or more of a first rotational axis, a second rotational axis, and a third translational axis. For example, the axes are orthogonal to each other. For example, the translation is simultaneous along two or more axes. For example, the oscillation is synchronous along two or more axes. For example, the oscillation frequency along a first axis is a harmonic of the oscillation frequency along a second axis.

The apparatus comprises a mounting support and a device chassis. The mounting support is, for example, a plate-based frame. For example, the mounting support comprises one or more of: a polymer, a fiber-reinforced polymer, a printed circuit board, and a flexible printed circuit board. For example, the mounting support is integrally a rigid printed circuit board. The mounting support may comprise a cutout within the mounting support, for example centered on the geometric center of the mounting support. The mounting support cutout has, for example, the same dimensions, for example within a margin of about 40%, for example about 25%, as the internal cutout in the device chassis. In particular, the center of the mounting support's cutout is aligned with the center of the device chassis' internal cutout.

The device chassis defines a plane (X-Y-plane) and a clockwise direction in the plane. The device chassis is, for example, formed from a sheet material. The device chassis may be formed from one or more of: a metal, a material comprising magnesium, a steel alloy , a spring steel, in particular 1.4310 or SAE 301; SAE grades 1070, 1074, 1075, 1080, 1095, 5160, 50CrV4, 9255; micro-alloyed steels, for example carbon-manganese steels and steels comprising one or more of boron, vanadium and niobium, bronze, brass, aluminum, titanium, a glass, a polymer, a ceramic, and a fiber-reinforced composite. The device chassis may be formed as a single component. In particular, the device chassis is a monolithically formed element. In other words, the constituents of the device chassis are made from the same piece of material in a continuous manner. For example, no fabrication of connections by means of welding, gluing, soldering or studding is performed, when fabricating the device chassis. For example, the device chassis is formed by cutting out, for example stamping, for example water or laser cutting, from a sheet material.

The device chassis may have a thickness, measured perpendicularly to the X-Y-plane, in a range from 0.05 mm to 0.5 mm. For example, for a device chassis made of spring steel 1.4310 material, the device chassis has a thickness in a range from 0.1 mm to 0.4 mm. The device chassis may have an overall length in a range from 5 mm to 100 mm. For example, the device chassis has an overall width in a range from 5 mm to 100 mm. For example, the device chassis made of 1.4310 material with a thickness in a range from 0.1 mm to 0.3 mm, in particular 0.15 mm has an overall length in a range from 14 mm to 52 mm, for example 35 mm and an overall width in a range from 9.5 mm to 50 mm, for example 35 mm.

The device chassis, although formed as an integral, single part, comprises a plurality of elements: a support frame, arm bridges, arms, standoff links and standoffs.

The support frame may be a planar element. The support frame may comprise an internal cutout, for example a rectangular cutout, for example dimensioned to accommodate the device. For example, a rectangular cutout, in a clockwise order, comprises a first side, a second side, a third side, and a fourth side. The device may be an optical element which comprises, for example, one or more of: a transparent device, for example, a panel, for example a planar transparent plate, a prism, a glass or polymer comprising one or more curved surfaces, for example a lens, a birefringent device; a reflective device, for example a mirror; a translucent device, for example comprising one or more of: a frosted glass or polymer, a surface-structured glass or polymer (for example comprising a random structure, for example comprising a spatially periodic structure, for example comprising a superposition or a juxtaposition of random and repetitive structures), and a grated glass or polymer; and a liquid crystal device, for example comprising one or more of: a light valve, a grating light valve, and a spatial light modulator. The optical device comprises, for example, one or more materials, for example one or more of: a glass, a silicate, a polymer, a metal-coated material, a metal oxide-coated material, and a material comprising an anti-reflective coating material.

The support frame may have an external contour, as seen from a top vie onto the X-Y-plane, which may be rectangular. Thus, the external contour may have four sides. The external contour may have one or more corner cutouts, for example each corner is cut out. The cut out may be a chamfer, for example at an angle with respect to one of the adjacent sides of the of the support frame, for example at an angle of 45°. In particular, the cutout may be filled.

The device chassis comprises at least a first arm bridge and a second arm bridge. The first arm bridge extends from a first side of the device chassis and the second arm bridge extends from a second side of the device chassis. The first side is opposed to the second side along the plane of the device chassis. In particular, the device chassis comprises four arm bridges. The device chassis may have essentially an external contour which is rectangular, as seen in a top view of the X-Y-plane, wherein one of the arm bridges extends from each side of the external contour. For example, an arm bridge is located at each side of the external contour, for example at opposing positions along the rectangular contour, for example one arm bridge at the middle position of each of the four sides of the rectangular contour.

Respectively the arm bridges are in direct contact with one of the sides of the device chassis. In particular, a portion of the side being in direct contact spans a range from about one twentieth to about four fifths, for example from about one fifth to about one quarter of the length of the side of the external contour from which the arm extends. For example, the side is in direct contact in a range from 2 mm to 40 mm. In particular, the arm bridge extends from the external contour by a length in a range from 1 mm to 30 mm.

The arm bridges provide, with respect to the mounting support, a rigid support for one or more arms, for example two arms extending in opposite directions along the side, for example a portion of the side, where the arm bridge is located. For example, each arm bridge is connected to a first arm extending continuously in a clockwise direction to a first standoff and a second arm extending continuously in an anti-clockwise direction to a second standoff. For example, the arm bridge neither bends nor twists with respect to the mounting support.

In this context “extending continuously” means that the arm does not reverse from a clockwise direction to an anti-clockwise direction along its extension path or vice versa. In particular one or multiple of the arms follow the external contour along a side of the external contour. In some embodiments, one or more arms extends parallel to a side of the external contour. For example, a side of an arm, for example the side nearest to the mounting support, extends parallel to the external contour. In some embodiments, the centerline of an arm extends parallel to the external contour. For example, when viewed from a direction orthogonal to the mounting support's plane, the first arm extends in a clockwise direction and the second arm extends in an anticlockwise direction. The first arm may be colinear with the second arm. For example, a rectangular or corner- truncated rectangular device support frame comprises four opposing pairs of arms. For example, each opposing pair of arms is mounted on a different side of the device chassis. For example, each opposing pair of arms is mounted on opposite sides of the device chassis, for example a device chassis comprising an even number of sides, for example four or more sides. In some embodiments, a first extremity of a first arm is in the continuity of a line extending from a first side of the internal cutout and a second extremity of a second arm is in the continuity of a line extending from a third side opposite to the first side of the internal cutout. Here and in the following an extremity is a section of an arm or a joiner, which protrudes along the main plane auf extension of said arm or joiner. In particular, the extremities may be utilized to connect the arm or joiner to an adjacent section of the device chassis.

In the location of the transition from the arm to the arm bridge, a notch is formed. Advantageously, the notch relieves stress at the location where the arm connects to the arm bridge. In particular the notch provides one or more of: a method to increase flexibility of the arm; a method to reduce metal fatigue at the connection of arm bridge an arm; and a method to increase apparatus longevity.

In some embodiments, a first arm from a first arm bridge on a first side is joined with a second arm from a second arm bridge on a second side adjacent to the first side. The first arm from the first arm bridge and the second arm from the second arm bridge may join via a joiner segment that is parallel to the corner cutout. The joiner segment extends straight along the X-Y-plane. In alternative embodiments, the joiner segment comprises one or more curved segments. In particular, a first extremity of the joiner segment is in the continuity of a line extending from a first side of the internal cutout and a second extremity of the joiner segment is in the continuity of a line extending from a second adjacent side of the internal cutout. For example, each side is adjacent to a first arm and a second arm. For example, each first arm and each second arm is connected by one of the joiner segments. For example, a rectangular or corner-truncated rectangular device mounting support comprises eight arms, for example with each first arm of a first arm bridge joined by a joiner segment to a second arm of a second arm bridge.

For example, the width of an arm is comprised in a range from 0.1 mm to 5 mm. One or more arms may have the same width at a first end of the arm, wherein the first end may be in direct contact with the arm bridge, and at a second end of the arm, wherein the second end is distal from the arm bridge. In particular, the first end has a width that is different from that of the second end. For example, the arm has a trapezium shape. The arm's width may be tapered from one end to another, for example from the first end to the second end.

For example, the length of an arm between the arm bridge and the joiner segment is comprised in a range from 2 mm to 40 mm. For example, the length of an arm joiner segment is comprised in a range from 1 mm to 20 mm.

Function. For example, an arm provides a tension spring. For example, the plurality of arms form a tension spring. For example, the tension spring formed by the plurality of arms form a method to allow motion along the Z axis.

The arms are connected to the standoffs by means of standoff links. The standoff links may be part of the device chassis. For example, each standoff link connects a joiner segment to a standoff. Each standoff may be connected to a joiner segment via one or more standoff links. In some embodiments, each standoff connects to a first arm of a first arm bridge and a second arm of a second arm bridge.

For example, the device support frame comprises four standoffs. The standoff may comprise one or more of: a triangular shape; a truncated triangular shape, for example truncated at the distal extremity from the geometric center of the internal cutout; for example, a rectangular shape; for example, a disc shape. For example, each standoff has an area comprised in a range from 2 mm² to 150 mm². For example, each standoff has an area in a range from 3 mm² to 22 mm² for example 12 mm².

According to one embodiment, the apparatus comprises one or more elastic standoff supports, which mechanically couple the standoff to the mounting support. One or more elastic standoff supports. A standoff support forms an elastic support between a standoff and a mounting support. In particular, each standoff is bonded to a standoff support.

The cross-section of the standoff support in the X-Y plane may match the contour of the standoff's shape. For example, the one or more standoff supports comprise one or more of: a parallelepiped geometry, a rectangular geometry, a cylindrical geometry, a pyramidal geometry, a spherical geometry, an annular geometry, a toroidal geometry, an I-beam geometry, and a U-beam geometry.

In some embodiments, one or more standoff supports, for example each standoff support, comprises a spring. For example, the spring comprises one or more of: a coil spring, a cantilever spring, a flat spring, a leaf spring, a torsion spring, a tension spring, a compression spring, a serpentine spring, a helical spring, a fluid-filled elastic envelope, and an elastic rod.

Advantageously the standoff supports provide a method to mechanically isolate motion, for example oscillations and/or vibrations, of the device chassis at a first end of the standoff support from a mounting support to which the standoff support is fixed at a second end of the standoff support. For example, a plurality of standoff supports provides mechanically isolates the device chassis from one or more of: deformations and vibrations of the mounting support. In particular, a deformation of the mounting support is caused by one or more of: strain; elongation; curvature; fastening-induced deformation, for example caused by differential forces at a plurality of fastening points; and temperature-induced deformation.

For example, one or more standoff supports comprises an elastomer material, for example a silicon-based organic polymer, for example a polydimethylsiloxane (PDMS). The elastomer material may have a Shore hardness measure of about 45 to 55, in particular 50. In some embodiments, the one or more standoff supports comprises a metallic spring. In a further embodiment, the one or more standoff supports comprises a fluid, for example one or more of: a gas, for example air; and a liquid, for example an oil. The one or more standoff supports may have a length in the Z-direction in a range from 0.5 mm to 4 mm, for example in a range from 0.6 mm to 1.9 mm, for example 1.5 mm. For example, all standoff supports have the same length.

According to one embodiment, the device chassis is formed as a single part comprising the two or more arm bridges, the first arm the second arm, the first standoff, and the second standoff.

According to one embodiment a first arm from a first arm bridge on a first side is connected to a second arm from a third arm bridge on a third side, wherein the third side is adjacent to the first side.

According to one embodiment the first arm extending from the first arm bridge on a first side is connected to the second arm from the third arm bridge on a third side, wherein the third side is adjacent to the first side. Moreover, a standoff link may connect the connected arms to a standoff.

According to one embodiment the one or more standoff supports comprises an elastomer material.

According to one embodiment the mounting support comprises one or more electrically conductive coils, the axis of which point out of the surface of the mounting support.

According to one embodiment the mounting support comprises an electrical printed circuit comprising one or more printed electrically conductive coils.

According to one embodiment the device chassis comprises one or more magnets.

According to one embodiment the mounting support comprises an electrical printed circuit comprising one or more printed electrically conductive coils, each coil facing a pole of one or more magnets bonded to the device chassis.

According to one embodiment one or more edges of one or more magnets is aligned with a midline of one or more conductive coils within a margin of about 20% of a conductive coil's track width.

According to one embodiment the first arm and the second arm extend from the respective arm bridge to the respective standoff, and during intended operation the bending moment and/or torque in the first arm and in the second arm is larger than bending moment and/or torque in the respective arm bridge and the respective standoff.

According to one embodiment the Youngs modulus of the elastic standoff supports is smaller than the Youngs modulus of the mounting support. In particular, the Youngs modulus of the standoff supports is at least 5 times smaller, preferably 10 times smaller, than the Youngs modulus of the mounting support. For example, the Youngs modulus of the mounting support is at least 100, preferably at least 150 GPa.

According to one embodiment, the Youngs modulus of the elastic standoff support is below 20 GPa, preferably below 10 GPa. In particular, the standoff support comprises a material having a shore hardness of less than Shore40A.

According to one embodiment, during intended operation the chassis is deflected along the Z-axis. In particular, the chassis is tilted about the X-axis and/or the Y-axis.

According to one embodiment, the first arm and the second arm are bent perpendicular with respect to their main direction of extension, and the bending moment is larger than the torque in the first arm and in the second arm.

### BRIEF DESCRIPTION OF DRAWINGS

FIG. 1A presents a perspective view of an apparatus for deflecting a device.

FIG. 1B presents a “see through” top view of the apparatus of FIG. 1A.

FIG. 2 presents a “see through” top view of an actuator assembly.

FIGS. 3A to 3F present top views of arm bridges and arms.

FIGS. 4A and 4B present side views of coils on a mounting support.

FIG. 4C presents a side view of an actuator assembly comprised in the apparatus.

FIG. 5 presents to assemble and configure magnets.

FIG. 6 shows a plurality of data points, for example stored in a lookup table.

FIGS. 7 to 10 show exemplary embodiments of an apparatus for deflecting in a schematic top view and a schematic side view.

### DESCRIPTION OF EMBODIMENTS

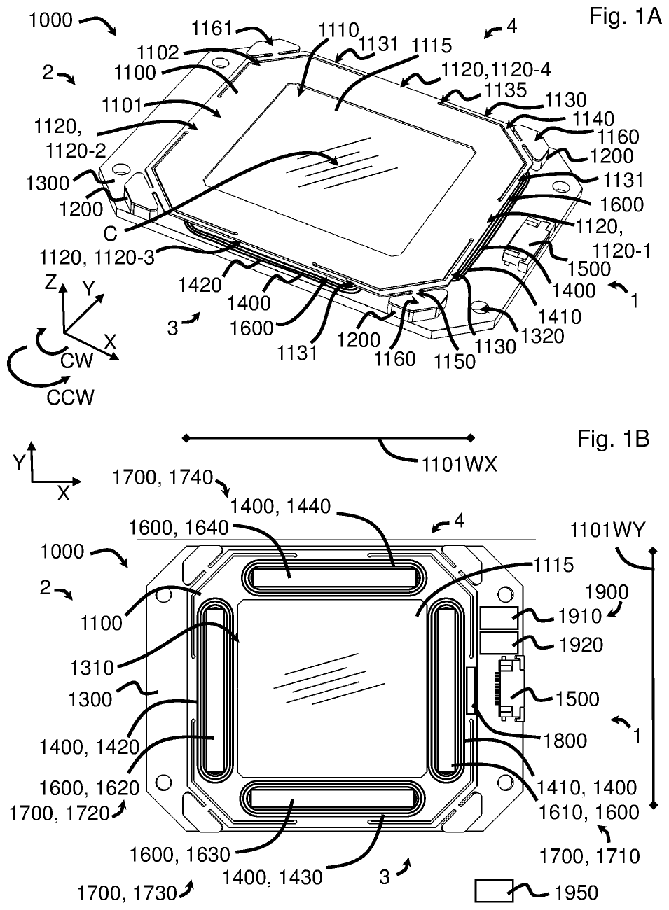

FIG. 1 A presents a perspective view of an apparatus 1000 for deflecting a device 1115 with respect to one or more axes, for example one or more of rotational and translational axes. The embodiment 1000 presented in FIGS. 1 A and 1B provides, for example, a method for deflecting the device 1115 in rotation around one or more of the axes X and Y and in translation along the axis Z. The apparatus 1000 further provides a method for oscillating the device 1115 in rotation around one or more of the axes X and Y and in translation along the axis Z. FIGS. 1 A and 1B present, for example, an apparatus for oscillating a device with respect to one or more axes, for example one or more of a first rotational axis, a second rotational axis, and a third translational axis. For example, the axes are orthogonal to each other. For example, the translation is simultaneous along two or more axes. For example, the oscillation is synchronous along two or more axes. For example, the oscillation frequency along a first axis is a harmonic of the oscillation frequency along a second axis.

The apparatus 1000 comprises, for example, a device chassis 1100. For example, the device chassis 1100 defines a plane X-Y and a clockwise direction CW in the plane X-Y. The device chassis 1100 is, for example, formed from a sheet material. For example, the device chassis 1100 is formed from one or more of: a metal, a material comprising magnesium, a steel alloy , a spring steel (for example 1.4310 or SAE 301; SAE grades 1070, 1074, 1075, 1080, 1095, 5160, 50CrV4, 9255; a micro-alloyed steel, for example a carbon-manganese steel; and a steel comprising one or more of boron, vanadium and niobium), a bronze, a brass, an aluminum, titanium, a glass, a polymer, a ceramic, and a fiber-reinforced composite.

For example, the device chassis 1100 has a thickness in a range from 0.05 mm to 0.5 mm. For example, for a device chassis made of spring steel 1.4310 material, the device chassis has a thickness in a range from 0.1 mm to 0.4 mm. For example, an embodiment of the device chassis has an overall length or width 1101WX, 1101WY in a range from 5 mm to 100 mm. For example, the device chassis has an overall width in a range from 5 mm to 100 mm. For example, an embodiment of a device chassis made of 1.4310 material with a thickness in a range from 0.1 mm to 0.3 mm, for example 0.15 mm has an overall length 1101WX in a range from 14 mm to 52 mm, for example 35 mm and an overall width 1101WY in a range from 9.5 mm to 50 mm, for example 35 mm.

For example, the device chassis 1100 is formed as a single component. For example, the device chassis 1100 is formed by cutting out, for example stamping, for example water or laser cutting, from a sheet material. The device chassis, for example formed as an integral, single part, comprises one or more regions, for example: a device support frame 1101; two or more arm bridges 1120 connected to the device support frame, for example four arm bridges 1120-1, 1120-2, 1120-3, 1120-4; a plurality of arms 1130, 1131 connected to the arm bridges; one or more standoff links 1150, each connected to one or more arms 1130, 1131; and one or more standoffs 1160, each connected to one or more standoff links 1150. For example, the device chassis has an overall rectangular geometry that, comprises a first side 1, a second side 2 opposite the first side, a third side 3 adjacent to the first and the second sides, and a fourth side 4 opposite the third side.

The device support frame 1101 is, for example, planar. An embodiment for a device support frame 1101 comprises, for example, an internal cutout 1110, for example a rectangular cutout, for example dimensioned to accommodate an optical device 1115. The optical device comprises, for example, one or more of: a transparent device, for example, a panel, for example a planar transparent plate, a prism, a glass or polymer comprising one or more curved surfaces, for example a lens, a birefringent device; a reflective device, for example a mirror; a translucent device, for example comprising one or more of: a frosted glass or polymer, a surface-structured glass or polymer (for example comprising a random structure, for example comprising a spatially periodic structure, for example comprising a superposition or a juxtaposition of random and repetitive structures), and a grated glass or polymer; and a liquid crystal device, for example comprising one or more of: a light valve, a grating light valve, and a spatial light modulator. The optical device comprises, for example, one or more materials, for example one or more of: a glass, a silicate, a polymer, a metal-coated material, a metal oxide-coated material, and a material comprising an anti-reflective coating material.

The device support frame 1101 comprises, for example, an external contour, for example comprising four sides, for example a rectangular contour. The external contour comprises, for example, one or more cutouts 1102. For example, the cutouts are corner cutouts, for example each corner of the device support frame's polygon is cut out as a chamfer 1102. For example, in an embodiment wherein the device support frame 1101 is rectangular, the chamfer 1102 is, for example, at an angle of 45° with respect to the sides adjacent to it. In some embodiments, the cutout is a fillet.

The device chassis 1100 comprises, for example, two or more arm bridges 1120. The arm bridge provides, with respect to the device support frame, a rigid support for one or more arms, for example two arms extending in opposite directions along the side, for example a portion of the side, where the arm bridge is located. For example, the arm bridge neither bends nor twists with respect to the device support frame. For example, a first arm bridge 1120-1, 1120-3 and a second arm bridge 1120-2, 1120-3 are located at respective opposite sides of the device chassis. For example, an arm bridge is located at each side of the external contour, for example at opposing positions along the rectangular contour, for example one arm bridge 1120 is connected, for example centered, to the middle position of each of the four sides of the rectangular contour of the device support frame 1101. For example, a portion of the length of a side of the external contour
comprises an arm bridge. For example, the portion of a side comprising an arm bridge spans a range from about one twentieth to about four fifths, for example from about one fifth to about one quarter of the length 1101WX, 1101WY of the side of the external contour from which the arm extends. For example, the portion of the side is comprised in a range from 2 mm to 40 mm. For example, the arm bridge extends from the external contour by a length in a range from 1 mm to 30 mm.

The device chassis 1100 comprises, for example, a plurality of arms 1130, 1131. For example, an arm provides a tension spring. For example, the plurality of arms form a tension spring. For example, the tension spring formed by the plurality of arms form a method to allow motion along the Z axis.

In some embodiments, one or more arm bridges 1120 comprises a first arm 1130 extending continuously in a clockwise direction (CW) to a first standoff 1160 and a second arm extending continuously in an anti-clockwise direction to a second standoff 1161. For example, the words “extending continuously” means that the arm does not reverse from a clockwise direction to an anti-clockwise direction along its extension path. In some embodiments, one or more arms follows the external contour along a side of the external contour. In some embodiments, one or more arms extends parallel to a side of the external contour. In some embodiments, a side of an arm, for example the side nearest to the support frame, extends parallel to the external contour. In some embodiments, the centerline of an arm extends parallel to the external contour. For example, when viewed from a direction orthogonal to the support frame's plane, the first arm extends in a clockwise direction and the second arm extends in an anticlockwise direction. In some embodiments, the first arm is colinear with the second arm. In some embodiments, a first extremity of a first arm is in the continuity of a line extending from a first side of the internal cutout and a second extremity of a second arm is in the continuity of a line extending from a third side opposite to the first side of the internal cutout.

In some embodiments, the location where the arm 1130, 1131 connects to the arm bridge 1120 comprises a notch 1135. The notch 1135 provides, for example, a method to relieve stress at the location where the arm connects to the arm bridge 1120. It is believed a notch provides one or more of: a method to increase flexibility of the arm; a method to reduce metal fatigue at the connection; and a method to increase apparatus longevity.

In some embodiments, a first arm 1130 from a first arm bridge 1120-1 on a first side 1 is joined with a second arm 1131 from a second arm bridge 1120-3 on a second side 3 adjacent to the first side 1. For example, this joining pattern is repeated for each arm 1130, 1131 of each arm bridge 1120, 1120-1, 1120-2, 1120-3, 1120-4. In some embodiments, the first arm 1130 from the first arm bridge 1120-1 and the second arm 1131 from the second arm bridge 1120-3 join via an arm joiner segment 1140 that is parallel to the corner cutout or chamfer 1102. In some embodiments, the joiner segment 1140 is a straight segment. In some embodiments, the joiner segment 1140 comprises one or more curves. In some embodiments, a first extremity of the joiner segment is in the continuity of a line extending from a first side of the internal cutout and a second extremity of the joiner segment is in the continuity of a line extending from a second adjacent side of the internal cutout. For example, each side 1, 2, 3, 4 comprises a first arm 1130 and a second arm 1131. For example, each first arm 1130 and each second arm 1131 is connected by an arm joiner 1140. For example, the length of an arm joiner segment is comprised in a range from 1 mm to 20 mm.

FIGS. 3A to 3F present embodiments of device chassis comprising various arm geometries. For example, the width of an arm 1130, 1131 is comprised in a range from 0.1 mm to 5 mm. An example embodiment of a device chassis 1100, 1100-1, 1100-2, 1100-6 comprises one or more arms 1130, 1131 that have the same width at a first end of the arm, for example the end closest to the arm bridge, as at a second end of the arm, for example the distal end from the arm bridge.

Another embodiment 1100-3, 1100-4, 1100-5 comprises one or more arms 1130, 1131 wherein the first end has a width that is different from that of the second end. For example, the arm has a trapezium shape. For example, the arm's width is tapered from one end to another, for example from the first end to the second end.

For example, the length of an arm between the arm bridge and the joiner segment is comprised in a range from 2 mm to 40 mm. For example, a rectangular or corner-truncated rectangular device support frame comprises 8 arms, for example with each first arm of a first arm bridge joined by a joiner segment to a second arm of a second arm bridge. For example, a rectangular or corner-truncated rectangular device support frame comprises 4 opposing pairs of arms 1130, 1131. For example, each opposing pair of arms is mounted on a different side 1, 2, 3, 4 of the device chassis. For example, each opposing pair of arms is mounted on opposite sides of the device chassis, for example a device chassis 1100 comprising an even number of sides, for example four or more sides.

The device chassis 1100 comprises, for example, a standoff link 1150 that extends from one or more of: a first arm 1130, and a second arm 1131. For example, a standoff link provides a torsion spring. In some embodiments, a standoff link 1150 extends from where a first arm 1130 and a second arm 1131 join. In some embodiments, the standoff link 1150 extends in the same plane as the device support frame. In some embodiments, the standoff link extends at an angle with respect to the plane X-Y of the device chassis. In some embodiments, the standoff link extends radially with respect to the geometric center C of the internal cutout 1110. In some embodiments, the standoff link 1150 extends radially with respect to the center of mass of the device chassis. In some embodiments, the standoff link extends at an angle within a range from −30° to +30°, for example 0°, with respect to a radial line extending from the geometric center C of the internal cutout. For example, a standoff link extends from each arm joiner 1140. In some embodiments, a standoff link extends from each arm 1130, 1131. For example, a rectangular or corner-truncated rectangular device chassis 1100 comprises 4 standoff links 1150. The length of a standoff link 1150 is, for example, comprised in a range from 0.2 to 5 mm.

The device chassis 1100 comprises, for example, one or more standoffs 1160. The device chassis 1100 comprises, for example, four standoffs 1160. For example, each standoff link 1150 connects a joiner segment 1140 to a standoff 1160. For example, each standoff 1160 connects to a joiner segment 1140 via one or more standoff links 1150. In some embodiments, each standoff 1160 connects to a first arm 1130 of a first arm bridge 1120-1 and a second arm 1131 of a second arm bridge 1120-3. For example, an embodiment of the device chassis 1100 comprises four standoffs 1160. For example, a standoff 1160 comprises one or more of: a triangular shape; a truncated triangular shape, for example truncated or chamfered at the distal extremity from the geometric center of the internal cutout; for example, a rectangular shape; for example, a disc shape. For example, each standoff 1160 has an area comprised in a range from 2 mm² to 150 mm². For example, each standoff 1160 has an area in a range from 3 mm² to 22 mm² for example 12 mm².

For example, embodiments apparatus 1000 for deflecting a device comprise one or more standoff supports 1200. A standoff support 1200 forms an elastic support between a standoff 1160 and a mounting support 1300. For example, each standoff 1160 is bonded to a standoff support 1200. For example, each of the standoffs 1160 is bonded to its respective one or more standoff supports 1200. For example, the apparatus 1000 comprises four standoff supports 1200, each of which connects to, for example is bonded to, a corresponding standoff 1160, for example one of four standoffs 1160. For example, in an embodiment of the standoff support 1200, the cross-section of the standoff support 1200 in the X-Y plane matches the contour of the standoff's contour. For example, the one or more standoff support 1200 comprises one or more of: a parallelepipedic geometry, a rectangular geometry, a cylindrical geometry, a pyramidal geometry, a spherical geometry, an annular geometry, a toroidal geometry, an I-beam geometry, and a U-beam geometry.

In some embodiments of the standoff support 1200, one or more standoff supports, for example each standoff support 1200, comprises a spring. For example, the spring comprises one or more of: a coil spring, a cantilever spring, a flat spring, a leaf spring, a torsion spring, a tension spring, a compression spring, a serpentine spring, a helical spring, a fluid-filled elastic envelope, and an elastic rod. For example, a plurality of standoff supports 1200 provides a method to mechanically isolate motion, for example oscillations, for example vibrations, of the device chassis 1100 at a first end of the standoff support 1200 from a mounting support 1300 to which the standoff support 1200 is fixed at a second end of the standoff support. For example, a plurality of standoff supports 1200 provides a method to mechanically isolate the device chassis from one or more of: deformations and vibrations of the mounting support. For example, a deformation of the mounting support is caused by one or more of: strain; elongation; curvature; fastening-induced deformation, for example caused by differential forces at a plurality of fastening points; and temperature-induced deformation.

For example, one or more standoff supports 1200 comprises an elastomer material, for example a silicon-based organic polymer, for example a polydimethylsiloxane (PDMS). The elastomer material has, for example, a Shore hardness measure of about 50. In some embodiments, the one or more standoff supports comprises a metallic spring. In a further embodiment, the one or more standoff supports 1200 comprise a fluid, for example one or more of: a gas, for example air; and a liquid, for example an oil. For example, one or more standoff supports 1200 have a length in the Z-direction in a range from 0.5 mm to 4 mm, for example in a range from 0.6 mm to 1.9 mm, for example 1.5 mm. For example, all standoff supports 1200 have the same length.

For example, an embodiment of the assembly comprising the device chassis 1100 and standoff supports 1200 has a natural frequency comprised in a range from 20 Hz to 5000 Hz, for example from 50 Hz to 1000 Hz, for example from 80 Hz to 500 Hz, for example one of: 90 Hz, 135 Hz, and 225 Hz.

For example, an embodiment of the apparatus 1000 comprises a mounting support 1300. For example, the mounting support 1300 is a plate-based device, for example a frame. In some embodiments, the mounting support 1300 comprises a cutout 1310 within the mounting support, for example centered on the geometric center of the mounting support. The mounting support cutout 1310 has, for example, the same dimensions, for example within a margin of about 40%, for example about 25%, as the internal cutout 1110 in the device chassis. For example, the center of the mounting support's cutout 1310 is aligned with the center C of the device chassis' internal cutout. The cutout 1310 provides a method, for example, to enable the passage of light to or from an optical device 1115 mounted on the device chassis 1100. In some embodiments, the mounting support 1300 has the same external dimensions, for example in one or more of length and width, as the device chassis 1100. In some embodiments, the mounting support 1300 comprises a dimension, for example a length, that is greater than that of the device chassis. For example, the dimension with greater length comprises one or more of a fastener, fastening points 1320, and an electrical connector 1500. In some embodiments, the mounting support 1300 comprises one or more mounting points, for example one or more holes 1320, for example 3 holes in a triangle, for example 4 holes, for example four holes arranged in a rectangle. The holes are, for example, dimensioned for the passage of one or more of: a screw; a knob; and a bushing, for example an elastomer bushing. In some embodiments the mounting point 1320 is represented as a cutout in the periphery of the board. In some embodiments the mounting point comprises a tenon, for example to be inserted into a clamp or slot. In some embodiments, one or more mounting points 1320 are located to be aligned with, for example, a first side and a second side, for example as depicted in FIGS. 1A and 1B the third side and the fourth side, of the device chassis' internal cutout 1110. For example, the mounting support 1300 comprises one or more of: a polymer, a fiber- reinforced polymer, a printed circuit board, and a flexible printed circuit board. For example, the mounting support 1300 is integrally a rigid printed circuit board.

FIG. 1B presents a “see through” top view along the Z-axis of the apparatus 1000. The “see through” view presents a plurality of actuator assemblies 1700 that are, for example, hidden from direct view along the Z-axis by the device chassis 1100 and the mounting support 1300. For example, the actuator assemblies 1700 are comprised between the device chassis 1100 and the mounting support 1300. For example, the apparatus 1000 comprises one or more actuator assemblies 1700. The actuator assemblies 1700 are, for example, comprised at one or more sides 1, 2, 3, 4 of the device chassis 1100. For example, the apparatus 1000 comprises one or more actuator assembly at each side 1, 2, 3, 4 of the device chassis 1100. For example, the apparatus 1000 comprises four actuator assemblies 1710, 1720, 1730, 1740 at each respective side 1, 2, 3, 4 of the apparatus. For example, each actuator assembly 1700 has a polygonal geometry, for example a rectangular or rounded rectangular geometry, and comprises a side that is parallel to a side 1, 2, 3, 4 of the internal cutout 1110.

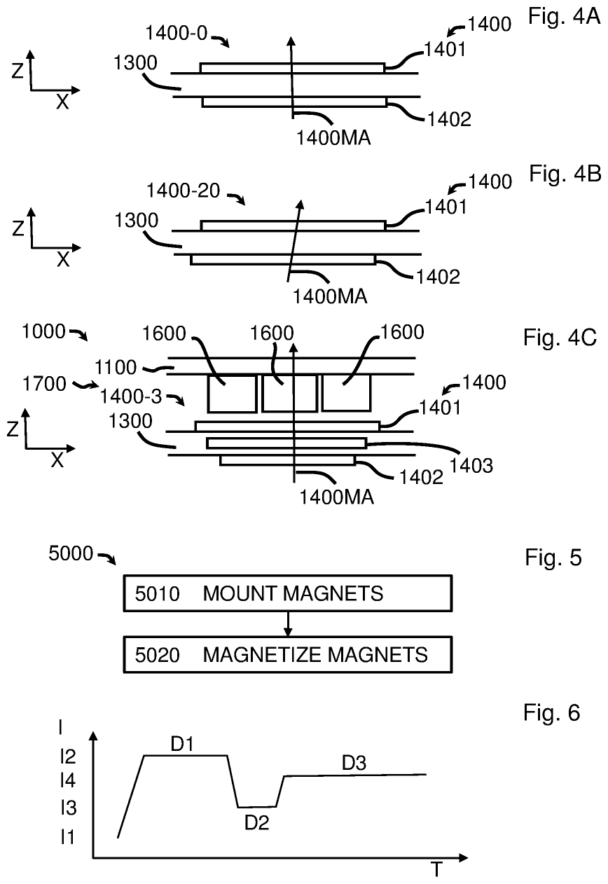

For example, an actuator assembly 1700 comprises one or more electrically conductive coils 1400 and one or more magnets 1600. For example, the apparatus 1000 presented in FIGS. 1 A and 1B comprises a first coil 1410, a second coil 1420, a third coil 1430, and a fourth coil 1440, each with a respective first magnet 1610, second magnet 1620, third magnet 1630, and fourth magnet 1640. For example, the magnetic axis 1400MA (shown in FIGS. 4A and 4B) of the one or more coils 1400 points out of the surface of the mounting support 1300, for example along the Z- direction. For example, the magnetic axis 1400MA of one or more of the one or more coils 1400 is within a margin of 20° from orthogonality to the surface of the mounting support. For example, the magnetic axis of the one or more coils 1400 is orthogonal to the surface of the mounting support 1300. For example, each of the one or more coils 1400 is printed as a plurality of series-connected concentric rings. In other embodiments, the one or more coils 1400 are printed as helical coils. For example, the one or more coils 1400 are positioned at one or more of: on the mounting support 1300, for example as a bonded flexible PCB; at the surface of the mounting support 1300, for example as a surface PCB; within the mounting support 1300, for example within one or more layers of the mounting support 1300 configured as a multilayer printed circuit board; and under the mounting support 1300, for example on the face of the mounting support 1300 that is opposite that of the device chassis 1100.

FIG. 4A presents, for example, an apparatus 1000 wherein one or more of the one or more coils 1400, presented as coil assembly 1400-0, comprises a first coil 1401 superimposed on a second coil 1402. FIG. 4B presents, for example, an apparatus 1000 wherein one or more of the one or more coils 1400, presented as coil assembly 1400-20, comprises a first coil 1401 superimposed on a second coil 1402 with an offset in one or more of the X- and the Y-directions. Superimposing a first coil 1401 on a second coil 1402 with an offset between the first and the second coil provides a method to form a coil assembly 1400, 1400-20 with a magnetic axis 1400MA that forms an angle that is not orthogonal to the mounting support 1300.

For example, the one or more magnets 1600 are bonded to the device chassis 1100. For example, one or more magnets 1600 faces one or more coils 1400. For example, each coil 1400 faces one magnet 1600. For example, a pole of the one or more magnets 1600 faces one or more of the one or more coils 1400. For example, each coil 1400 comprises a rounded rectangle contour. For example, each magnet 1600 has the same length and the same width as the coil it faces.

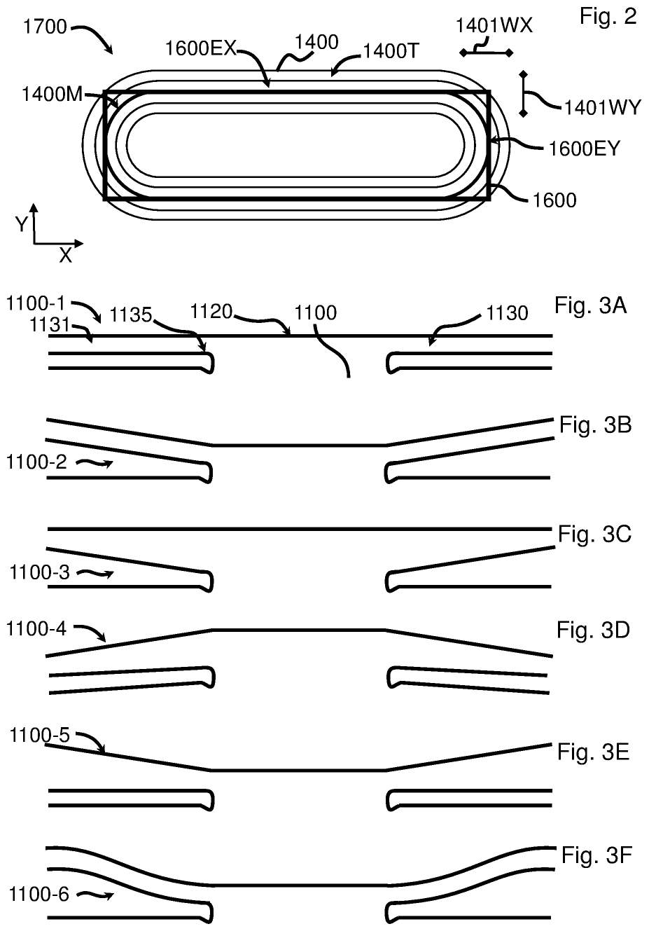

FIG. 2 shows a coil track 1400T, for example of a coil 1400 comprised on a printed circuit board, for example embodied as mounting support 1300. The coil track 1400T is the region comprised between the innermost coil loop and the outermost coil loop of the coil 1400. The midline 1400M of a coil's track is a theoretical line tracing the points halfway between the innermost coil loop and the outermost coil loop. In some embodiments, one or more of the edges 1600EX, 1600EY of one or more magnets is aligned with a line running parallel to the midline 1400M of the coil's track 1400T, for example within a margin of about 20% of the track's width 1401WX, 1401WY off the midline of the coil's track. For example, an edge 1600EX of the magnet parallel to the X-direction is aligned with about the midline 1400M of the coil's track running in the X-direction. For example, an edge 1600EY of the magnet parallel to the Y-direction is aligned with about the midline 1400M of the coil's track running in the Y-direction. An edge 1600EX, 1600EY of a magnet is, for example, comprised in a plane defining a contour of the magnet's face that faces the coil.

FIG. 4C presents a side view of an embodiment 1400-3 for a coil 1400 wherein the coil comprises a V-shaped contour. For example, a cross-section of the coil 1400 in a plane comprising the coil's magnetic axis 1400MA presents a V-shaped or trapezoidal geometry. In FIG. 4C, a third coil is, for example, embedded as a layer within the mounting support 1300, for example formed as a printed circuit board. In some embodiments of an actuator assembly 1700, two or more adjacent magnets 1600 face a same coil 1400, for example a V-shaped coil 1400-3.

For example, the apparatus 1000 comprises one or more opposing coil pairs, for example coil 1410, 1430 opposing coil 1420, 1440, respectively. An opposing coil pair comprises a first coil 1410, 1430 wound in a first direction, for example clockwise CW, and a second coil 1420, 1440 wound in an opposite second direction, for example counter-clockwise CCW. For a first example, the mounting support comprises a first coil 1410, 1430 wound in the first direction facing a first magnet 1610, 1630 bonded to the device chassis along the first (or third) side of the internal cutout and the second coil 1420, 1440 wound in the second direction facing a second magnet 1620, 1640 bonded to the device chassis along the second (or fourth) opposite side of the internal cutout. In the first example, the orientation of the magnetization of the first magnet 1610, 1630 and the second 1620, 1640 magnet is the same. In some embodiments, the first coil 1410, 1430 and the second coil 1420, 1440 are connected in series. In some embodiments, the first coil 1410, 1430 and the second coil 1420, 1440 are connected in parallel.

For example, the apparatus 1000 comprises a plurality of opposing coil pairs. For example, each pair of opposing (1, 2), (3, 4) sides of the internal cutout 1110 comprises an opposing coil pair (1410, 1420), (1430, 1440). For example, an apparatus comprises a first opposing coil pair (1410, 1420) along a first axis X at first opposing sides (1, 2) with respect to the internal cutout, for example the center C of the internal cutout 1110, and a second opposing coil pair (1430, 1440) along a second axis Y at second opposing sides(3, 4) with respect to the internal cutout 1110. For example, the first axis X and the second axis Y are at an angle of 90° with respect to each other, for example in a plane parallel to that of the device chassis. For example, the apparatus comprises a first coil 1410 wound in the first direction CW at the first side 1, a second coil 1420 wound in the second direction CCW at the second side 2, a third coil 1430 wound in one of the first or second directions at the third side 3, and a fourth coil 1440 wound in a direction opposite to that of the third coil 1430 at the fourth side 4. For example, the geometry of the contour of the internal cutout 1110 does not relate to the number and position of the opposing coil pairs 1400. For example, a circular or polygonal cutout 1110 is lined with two or more opposing coil pairs (1410, 1420), (1430, 1440). In some embodiments, the number of coil pairs (1410, 1420), (1430, 1440) defines the number of axes X, Y upon which the device chassis is primarily deflectable. In some embodiments, actuation along or around one or more axes, for example rotation around a first axis X and a second axis Y, provides a method to induce deflection, for example translation, along a third axis Z.

The magnets 1600 are, for example, pre-magnetized magnets, for example magnetized prior to assembly. In another example embodiment of the apparatus 1000, the magnets 1600 are assembled onto the chassis unmagnetized. FIG. 5 presents, for example, an assembly method 5000 comprises the step of mounting 5010, for example bonding, the one or more magnets 1600 in an unmagnetized state onto the chassis and a step of magnetizing 5020 the one or more magnets during one or more of: during the assembly, and after the assembly. The magnets 1600 comprise, for example, one or more of neodymium, samarium, cobalt, and any other magnetic material.

The mounting support 1300 comprises, for example, one or more electrical connectors 1500, for example comprising one or more of: a power supply line, a control signal line, a sensor signal line, and a digital communication line.

In some embodiments, the apparatus 1000 comprises one or more sensors 1800, for example mounted on the mounting support 1300. For example, the one or more sensors 1800 provides a method to measure one or more of: the position of the device chassis 1100 with respect to the mounting support 1300; the displacement speed of the device chassis 1100 with respect to the mounting support 1300; the frequency of displacement of the device chassis 1100 with respect to the mounting support 1300; and the temperature of one or more parts of the apparatus 1000. For example, the one or more sensors 1800 comprises: a Hall sensor, a magnetic sensor, a capacitve sensor, an optical sensor, an imaging sensor, a resistive sensor, a piezo-electric sensor, an accelerometer, a strain gauge, and a temperature sensor. For example, an optical sensor measures one or more of transmitted light, reflected light, diffracted light, and stray light.

In some embodiments, the apparatus 1000 comprises one or more digital processors 1910. For example, the one or more processors are comprised in a controller 1900. For example, the one or more digital processors 1910 is connected, for example via a communication interface, to one or more of: a computer-readable non-volatile storage device 1920; one or more actuators 1700; one or more sensors 1800; and one or more digital data communication ports, for example a wireless communication device or a port comprised in the connector 1500. In some embodiments, the apparatus 1000 comprises a computer-readable non-volatile storage device 1920. In some embodiments, the computer-readable non-volatile storage device 1920 is connected via a data communication port, for example the connector 1500, to an external processor 1950, for example one or more of: a digital controller, a digital light processing (DLP) processor, and a chipset comprising one or more digital processors.

For example, the computer-readable non-volatile memory device 1920 comprises instructions to configure a processor 1910, 1950. The instructions comprise, for example, one or more parameters of: a resonant frequency parameter; a quality factor parameter, for example related to the device's resonant frequency characteristics; one or more actuator constants, for example one or more constants relating a required electrical supply characteristic with a measured temperature, for example relating a required current supply to a measured temperature; and one or more device chassis 1100 desired transition time from a first deflection position to a second deflection position, for example from a first extreme deflection position to a second opposite extreme deflection position. For example, the one or more actuator constants comprise one or more linear temperature compensation constants, for example one or more temperature compensation gains, for example stored in a lookup table.

For example, the instructions comprise parameters to modulate the current supplied to the one or more coils 1400, for example the four coils 1410, 1420, 1430, 1440, to drive the oscillatory deflection of the device chassis 1100. For example, the instructions comprise a table comprising one or more pluralities of data coordinates, for example data points, describing the amplitude of an electrical supply with respect to time, for example a current versus time graph, for example to define one or more of: a current signal to form a rising edge deflection, and a falling edge deflection. For example, a plurality of data points comprises 512 or more points. For example, one or more parameters or data points are stored in a lookup table. For example, as shown in FIG. 6, a first plurality of data points comprises an increase from a first value 11 to a second value 12 followed by a decrease to a third value 13 followed by an increase to a fourth value 14. For example, the duration D1 of the second value is shorter than the duration D3 of the fourth value. For example, the second value 12 is equal to the fourth value 14. For example, a second plurality of data points comprises a reverse sequence of the first plurality of data points. For example, the second plurality of data points comprises a decrease from the fourth value 14 to the third value 13 followed by an increase to the second value 12 followed by a decrease to the first value 11. For example, the first plurality of data points defines a rising edge characterizing the deflecting motion of the device chassis to a first position. For example, the second plurality of data points defines a falling edge characterizing the deflecting motion of the device chassis to a second position.

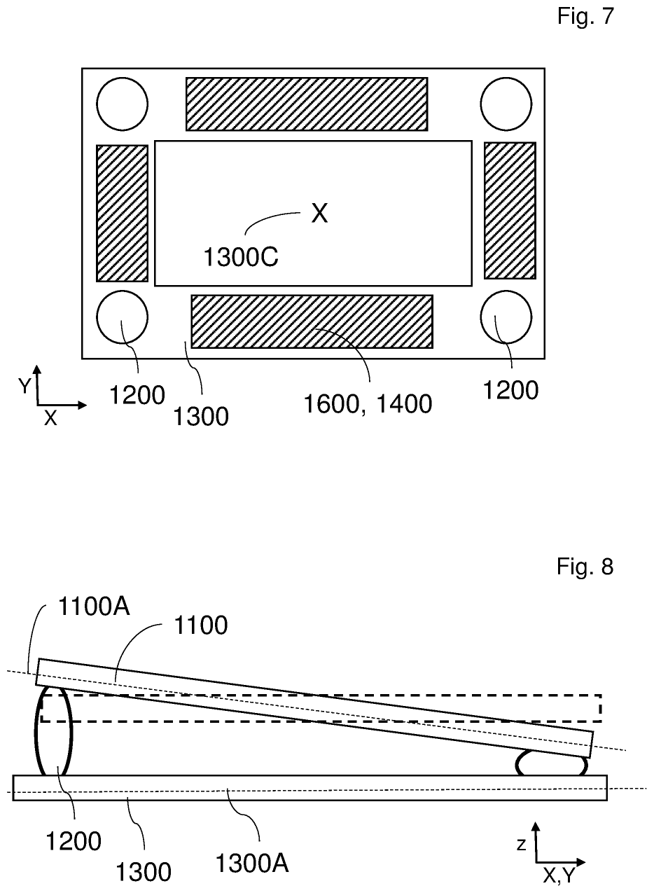

FIGS. 7 to 10 show exemplary embodiments of an apparatus for deflecting in a schematic top view and a schematic side view. The apparatus 1000 is arranged to deflect a device 1115 with respect a mounting support 1300. The device 1115 is fixedly attached to a device chassis 1100. The device chassis 1100 is mechanically coupled to the mounting support 1300 by means of at least one standoff support 1200, wherein the device chassis is arranged to be deflected with respect to the mounting support by means of elastic deformation of the standoff support 1200. Elastic deformation may comprise bending of the standoff support in a direction perpendicular with respect to the z-axis. Elastic deformation may comprise compression and extension of the standoff support along the z-axis

The device chassis 1100 extends along a first plane 1100A and the mounting support 1300 extends along a second plane 1300A. The standoff support 1200 is arranged in the interspace between the first plane 1100A and the second plane 1300A.

The Youngs modulus of the standoff support 1200 is smaller than the Youngs modulus of device chassis 1100 and the Youngs modulus of the mounting support 1300 respectively. For example, the standoff support comprises a material having a shore hardness of less than Shore10A.

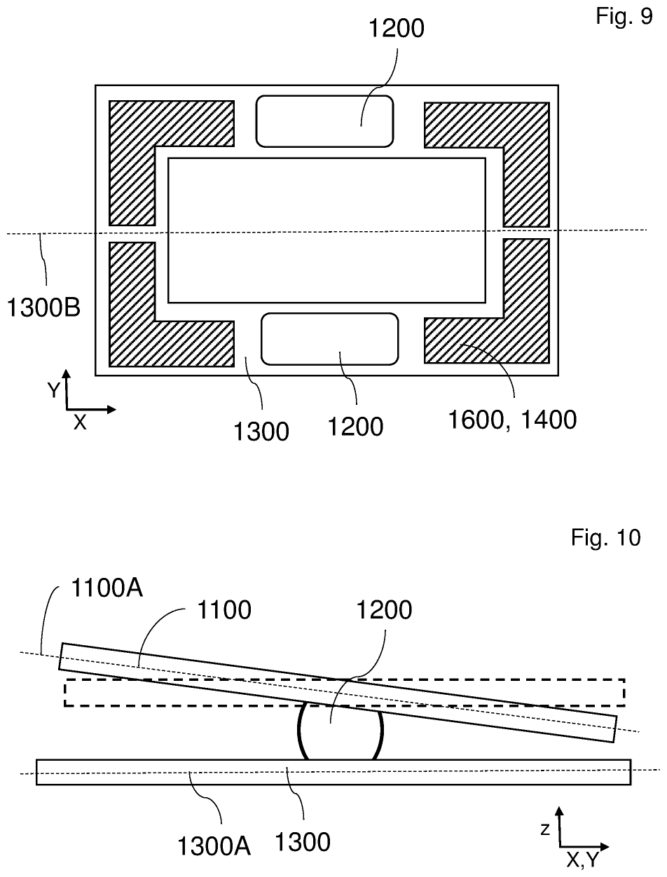

The device comprises multiple standoff supports 1200, wherein at least two of the standoff supports 1200 are arranged symmetrically with respect to an axis of symmetry 13008 (see FIG. 9) or a point of symmetry 1300C (see FIG. 7) of the device chassis 1100 seen in a top view along a common axis of symmetry.

The apparatus comprises at least one coil 1400 and at least one magnet 1600. The at least one coil 1400 is fixedly attached to the device chassis 1100 and the at least one magnet 1600 is fixedly attached to the mounting support 1300 or vice versa. An electromagnetic force between the at least one magnet 1600 and the at least one coil 1400 results in the deflection of the device 1115.

1. An apparatus (1000) for deflecting with respect to one or more axes a device (1115) mounted on the apparatus (1000), the apparatus (1000) comprising:
a mounting support (1300);
a device chassis (1100) defining a plane (X-Y) and a clockwise direction (CW) in the plane (X-Y),
wherein the device chassis (1100) comprises two or more arm bridges (1120),
wherein a first arm bridge (1120-1) is extending from a first side (1) of the device chassis (1100) and a second arm bridge (1120-2) is extending from a second and opposite side (2) of the device chassis (1100), and
wherein one or more arm bridges (1120) comprises:
a first arm (1130) extending continuously in a clockwise direction (CW) to a first standoff (1160)
and a second arm (1131) extending continuously in an anti-clockwise direction to a second standoff (1161); and
one or more standoff supports (1200) comprised between each standoff (1160, 1161) and the mounting support (1300).

2. The apparatus of claim 1, wherein the device chassis (1200) is formed as a single part comprising the two or more arm bridges (1120), the first arm (1130), the second arm (1131), the first standoff (1160), and the second standoff (1161). The apparatus of claim 1, wherein the device chassis (1200) is formed from a sheet material selected from the group consisting of: a sheet of spring steel, a sheet of micro-alloyed steel, a sheet of carbon-manganese steel, a sheet of steel comprising boron, a sheet of steel comprising vanadium, a sheet of steel comprising niobium, a sheet of metal comprising magnesium, a sheet of metal comprising bronze, a sheet of metal comprising brass, a sheet of metal comprising aluminum, a sheet of metal comprising titanium, a sheet comprising a glass material, a sheet comprising a polymer material, a sheet comprising a ceramic material, and a sheet comprising a fiber-reinforced composite material.

4. The apparatus of claim 1, wherein the device (1115) is an optical device selected from the group consisting of: a transparent plate, a prism, a birefringent plate, a mirror, a lens, a surface-structured glass, a surface-structured polymer, and a liquid crystal device.

5. The apparatus of claim 1, wherein a first arm (1130) from the first arm bridge (1120-1) on the first side (1) is connected to the second arm (1131) from a third arm bridge (1120-3) on a third side (3) adjacent to the first side (1).

6. The apparatus of claim 1, wherein the first arm (1130) from the first arm bridge (1120-1) on the first side (1) is connected to the second arm (1131) from the third arm bridge (1120-3) on the third side (3) adjacent to the first side (1) and a standoff link (1150) connects the connected first and second arms (1130, 1131) to the standoff (1160).

7. The apparatus of claim 1, wherein the one or more standoff supports (1200) comprise an elastomer material.

8. The apparatus of claim 1, wherein the mounting support (1300) comprises one or more electrically conductive coils (1400), the axis of which point out of a surface of the mounting support (1300).

9. The apparatus of claim 8, wherein the mounting support (1300) comprises an electrical printed circuit comprising one or more printed electrically conductive coils (1400)

10. The apparatus of claim 1, wherein the device chassis (1100) comprises one or more magnets (1600).

11. The apparatus according to claim 1, wherein
the first arm (1130) and the second arm (1131) extend from the respective arm bridge (1120) to the respective standoff (1160), and
during intended operation the bending moment and/or torque in the first arm (1130) and in the second arm (1131) is larger than bending moment and/or torque in the respective arm bridge (1120) and the respective standoff (1160).

12. The apparatus according to claim 1, wherein the Youngs modulus of the elastic standoff supports (1200) is smaller than the Youngs modulus of the mounting support (1300).

13. The apparatus according to claim 1, wherein the Youngs modulus of the elastic standoff support is below 20 GPa.

14. The apparatus according to claim 1 wherein during intended operation the chassis is deflected along the Z-axis.

15. The apparatus according to claim 1, wherein the first arm (1130) and the second arm (1131) are bent perpendicular with respect to their main direction of extension, and the bending moment is larger than the torque in the first arm (1130) and in the second arm (1131).

16. An apparatus (1000) for deflecting a device (1115) with respect a mounting support (1300), wherein
the device (1115) is fixedly attached to a device chassis (1100),
the device chassis (1100) is mechanically coupled to the mounting support (1300) by means of at least one standoff support (1200), wherein
the device chassis is arranged to be deflected with respect to the mounting support by means of elastic deformation of the standoff support (1200),
the device chassis (1100) extends along a first plane (1100A), the mounting support (1300) extends along a second plane (1300A), and
the standoff support (1200) is arranged in the interspace between the first plane (1100A) and the second plane (1300A).

17. The apparatus according to claim 16, wherein the Youngs modulus of the standoff support (1200) is smaller than the Youngs modulus of device chassis (1100) and the Youngs modulus of the mounting support (1300) respectively.

18. The apparatus according to claim 16, wherein
the device comprises multiple standoff supports (1200),
at least two of the standoff supports (1200) are arranged symmetrically with respect to an axis of symmetry (1300B) or a point of symmetry (1300C) of the device chassis (1100) seen in a top view along a common axis of symmetry.

19. The apparatus according to claim 16 comprising at least one coil (1400) and at least one magnet (1600), wherein
the at least one coil (1400) is fixedly attached to the device chassis (1100) and the at least one magnet (1600) is fixedly attached to the mounting support (1300) or vice versa, and
an electromagnetic force between the at least one magnet (1600) and the at least one coil (1400) results in the deflection of the device (1115).
